(19) United States
(12) Patent Application Publication
(10) Pub. No.: US 2026/0182273 A1
(43) Pub. Date: Jun. 25, 2026

(54) METHOD OF MANUFACTURING NITROGEN-DOPED SILICON SUBSTRATE

(71) Applicant: SAMSUNG ELECTRONICS CO., LTD., Suwon-si (KR)

(72) Inventors: Junyoung Oh, Suwon-si (KR); Youngsoo Park, Suwon-si (KR); Yunho Kim, Suwon-si (KR); Junghoon Lee, Suwon-si (KR); Samjong Choi, Suwon-si (KR); Wiseok Kang, Suwon-si (KR); Hoonjoo Park, Suwon-si (KR)

(73) Assignee: SAMSUNG ELECTRONICS CO., LTD., Suwon-si (KR)

(21) Appl. No.: 19/249,479

(22) Filed: Jun. 25, 2025

(30) Foreign Application Priority Data
Dec. 23, 2024 (KR) 10-2024-0194680

(51) Int. Cl. H01L 21/225; C30B 13/12; C30B 29/06; C30B 31/18

(52) U.S. Cl. CPC H10P 32/14; C30B 13/12; C30B 29/06; C30B 31/185; H10P 32/171

(57) ABSTRACT

A method of forming a nitrogen-doped silicon substrate by doping nitrogen in an edge portion of a base substrate including a central portion and an edge portion is provided. The method includes: providing a first mask on a surface of the base substrate to cover a central portion and an inner edge portion, and to expose an outer edge portion; performing a primary doping operation of doping nitrogen on the outer edge portion while the first mask is on the surface of the base substrate; providing a second mask on the surface of the base substrate to cover the central portion, and to expose the outer edge portion and the inner edge portion; performing a secondary doping operation of doping nitrogen on the outer edge portion and the inner edge portion while the second mask is on the surface of the base substrate.

### CROSS-REFERENCE TO RELATED APPLICATION

This application claims priority under 35 U.S.C. § 119 to Korean Patent Application No. 10-2024-0194680, filed on Dec. 23, 2024, in the Korean Intellectual Property Office, the disclosure of which is incorporated by reference herein in its entirety.

### BACKGROUND

The present disclosure relates to a method of manufacturing a nitrogen-doped silicon substrate, and more particularly, to a method of manufacturing a silicon substrate having nitrogen doped at an edge portion.

Silicon wafers for semiconductor processes used in the manufacture of electronic components may be obtained by growing an ingot and then slicing the grown ingot. Because cracks may occur at edges during a grinding process when the strength of a wafer is low, research is being conducted to improve the mechanical stability of the wafer.

Wafers sliced from nitrogen-doped silicon crystals are known to help improve the strength of a wafer, but because nitrogen is doped on the entire surface of the wafer, it may affect devices formed later.

### SUMMARY

One or more embodiments provide a method of manufacturing a silicon substrate with improved mechanical stability and electrical reliability.

One or more embodiments provide a method of manufacturing a nitrogen-doped silicon substrate.

According to an aspect of an embodiment, a method of manufacturing a nitrogen-doped silicon substrate, includes: preparing a base substrate which is circular and includes a central portion, an inner edge portion surrounding the central portion in a ring shape, and an outer edge portion surrounding the inner edge portion in a ring shape, the base substrate including a first surface and a second surface opposite to the first surface; providing a first mask on the first surface of the base substrate to cover the central portion and the inner edge portion, and to expose the outer edge portion; performing a primary doping operation of doping nitrogen on the outer edge portion while the first mask is on the first surface of the base substrate; removing the first mask and providing a second mask on the first surface of the base substrate to cover the central portion, and to expose the outer edge portion and the inner edge portion; performing a secondary doping operation of doping nitrogen on the outer edge portion and the inner edge portion while the second mask is on the first surface of the base substrate; and removing the second mask. An atomic concentration of nitrogen in the inner edge portion is constant at a first concentration, an atomic concentration of nitrogen in the outer edge portion is constant at a second concentration. An atomic concentration of nitrogen changes discontinuously from the first concentration to the second concentration at a boundary between the outer edge portion and the inner edge portion.

According to another aspect of an embodiment, a method of manufacturing a nitrogen-doped silicon substrate, includes: injecting a silicon powder into a cylindrical mold of an ingot manufacturing device; injecting a nitride powder into a nitrogen powder injection path in the ingot manufacturing device, wherein the nitrogen powder injection path surrounds the cylindrical mold in a ring shape; applying a first pressure to compress the silicon powder and form a silicon powder lump in a polycrystalline state; applying heat to the silicon powder lump and recrystallizing the silicon powder lump into a single crystal structure; forming an ingot from the silicon powder lump; and slicing the ingot to form individual substrates. In the recrystallizing of the silicon powder lump, nitrogen is doped on a side surface of the ingot by the nitride powder injected through the nitrogen powder injection path.

According to another aspect of an embodiment, a method of manufacturing a nitrogen-doped silicon substrate, includes: in an ingot manufacturing device including a cylindrical mold and a nitrogen coating portion wrapping around the cylindrical mold in a ring shape, forming a polycrystalline silicon rod within the cylindrical mold; heating, by the nitrogen coating portion, a side surface of the polycrystalline silicon rod placed within the cylindrical mold; doping a nitride series material on the side surface of the polycrystalline silicon rod; recrystallizing the polycrystalline silicon rod into an ingot; and slicing the ingot to form individual substrates. At least one of the individual substrates includes a nitrogen doping area formed in a ring shape at an edge portion.

According to another aspect of an embodiment, a base substrate includes: a central portion having a nitrogen concentration of zero; an inner edge region portion which surrounds the central portion and has a first nitrogen concentration; and an outer edge region portion which surrounds the inner edge region portion and has a second nitrogen concentration. The first and second nitrogen concentrations are both greater than zero, and the second nitrogen concentration is greater than the first nitrogen concentration.

The base substrate may have a circular shape.

A radius of the base substrate may be 150 mm.

A border between the central portion and the inner edge region may correspond to a circle having a radius of 147 mm to 149 mm.

A border between the inner edge region and the outer edge region may correspond to a circle having a radius greater than 149 mm.

### BRIEF DESCRIPTION OF DRAWINGS

The above and other aspects will be more apparent from the following description of embodiments taken in conjunction with the accompanying drawings, in which:

FIG. 1A illustrates a schematic diagram of a nitrogen-doped silicon substrate according to an embodiment;

FIG. 1B is a graph showing a nitrogen concentration included in a nitrogen-doped silicon substrate according to an embodiment;

FIG. 2A illustrates a schematic drawing of a nitrogen-doped silicon substrate according to an embodiment;

FIG. 2B is a graph showing a nitrogen concentration included in a nitrogen-doped silicon substrate according to an embodiment;

FIGS. 3A, 3B, 3C and 3D are drawings sequentially illustrating a method of manufacturing a nitrogen-doped silicon substrate, according to an embodiment;

FIG. 4A is a cross-sectional view schematically illustrating a manufacturing process of a nitrogen-doped silicon substrate, according to an embodiment; and

FIG. 4B is a cross-sectional view schematically illustrating a manufacturing process of a nitrogen-doped silicon substrate, according to an embodiment.

### DETAILED DESCRIPTION

Hereinafter, embodiments are described with reference to the attached drawings. The same reference symbols are used for identical components in the drawings, and descriptions already given for the identical components may be omitted. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

These embodiments may be modified in various ways and have many different embodiments, and specific embodiments are illustrated in the drawings and described in detail in the detailed description. However, this is not intended to limit the scope to specific embodiments, but should be understood to include all transformations, equivalents, or alternatives included in the scope of disclosed ideas and techniques.

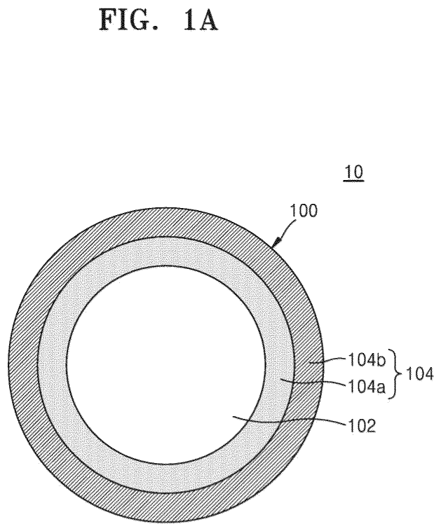

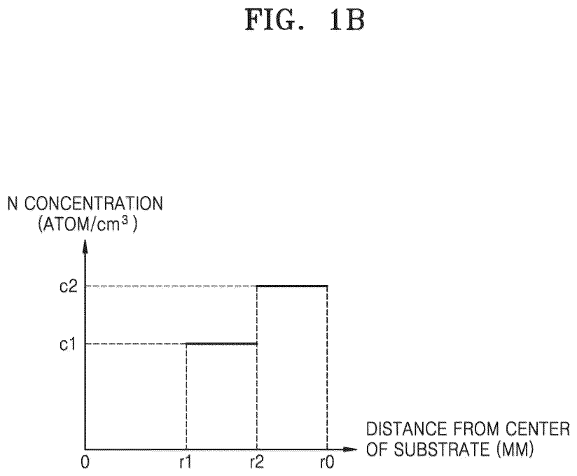

FIG. 1A illustrates a schematic diagram of a nitrogen-doped silicon substrate 10 according to an embodiment, and FIG. 1B is a graph showing a nitrogen concentration included in the nitrogen-doped silicon substrate 10 of FIG. 1A.

Referring to FIGS. 1A and 1B, the nitrogen-doped silicon substrate 10 may be a base substrate 100 including an edge portion 104 and a central portion 102.

The base substrate 100 may include a first surface and a second surface facing away from each other, and a surface illustrated in FIG. 1A may be the first surface of the base substrate 100. The base substrate 100 may include an element area and an edge area surrounding the element area. The element area may be an area where a plurality of element patterns are formed on the base substrate 100. That is, the element patterns may be formed on the first surface of the base substrate 100. The edge area may surround the element area. The edge area may indicate a bevel edge of the base substrate 100.

The base substrate 100 may be a bulk silicon or silicon-on-insulator (SOI). The base substrate 100 may be a silicon substrate, or may include other materials, such as, but not limited to, silicon germanium, silicon germanium on insulator (SGOI), indium antimonide, lead tellurium compound, indium arsenide, indium phosphide, gallium arsenide, or gallium antimonide.

The central portion 102 of FIG. 1A may correspond to the element area of the base substrate 100, and the edge portion 104 may correspond to the edge area of the base substrate 100. However, embodiments are not limited thereto. In some other embodiments, the element area of the base substrate 100 may be included in the central portion 102 of FIG. 1A, and the edge area may be included in both the central portion 102 and the edge portion 104. The element area of the base substrate 100 may be an area that is not doped with nitrogen, and the edge area of the base substrate 100 may include both an area that is not doped with nitrogen and an area that is doped with nitrogen.

In this specification, expressions such as ‘nitrogen atom’ and ‘nitrogen’ may refer to all forms of N, including N included in a compound (e.g., a nitride series compound).

The central portion 102 of the base substrate 100 may include Si. In embodiments, the central portion 102 of the base substrate 100 may not include nitrogen. For example, the central portion 102 of the base substrate 100 may include only trace amounts of nitrogen.

The edge portion 104 of the base substrate 100 may include nitrogen. The edge portion 104 of the base substrate 100 may include an outer edge portion 104b and an inner edge portion 104a. A concentration of nitrogen included in the outer edge portion 104b may be greater than the concentration of nitrogen included in the inner edge portion 104a. As nitrogen is not included in the central portion 102, concentration of nitrogen included in each of the outer edge portion 104b and the inner edge portion 104a is greater than the concentration of nitrogen in the central portion 102. In embodiments, the inner edge portion 104a may wrap around the central portion 102 in a ring shape, and the outer edge portion 104b may wrap around the inner edge portion 104a in a ring shape. A diameter of the outer edge portion 104b may be the same as a diameter of the base substrate 100. The diameter of the outer edge portion 104b may be greater than a diameter of the inner edge portion 104a, and the diameter of the inner edge portion 104a may be greater than the diameter of the central portion 102.

Referring to FIGS. 1A and 1B together, a radius of the outer edge portion 104b may be a reference length r0, the radius of the inner edge portion 104a may be a second length r2, and a radius of the central portion 102 may be a first length r1. An area from a center of the base substrate 100 to the first length r1 may correspond to the central portion 102 of the base substrate 100, an area spaced apart from the center of the base substrate 100 by a length greater than the first length r1 and less than or equal to the second length r2 may correspond to the inner edge portion 104a of the base substrate 100, and an area spaced apart from the center of the base substrate 100 by a length greater than the second length r2 and less than or equal to the reference length r0 may correspond to the outer edge portion 104b of the base substrate 100.

In some embodiments, a difference between the first length r1 and the second length r2 may be equal to a difference between the second length r2 and the reference length r0, but embodiments are not limited thereto. The difference between the first length r1 and the second length r2 may be greater than or less than the difference between the second length r2 and the reference length r0.

In embodiments, the base substrate 100 may be a 12-inch silicon substrate. When the base substrate 100 is a 12-inch silicon substrate, the reference length r0, which is a radius of the base substrate 100, may be about 150 mm. In this case, the edge portion 104 may be an area spaced about 147 mm to about 150 mm apart from the center of the base substrate 100. For example, the edge portion 104 may be an area spaced apart from the center of the base substrate 100 by 149 mm to 150 mm.

In embodiments, when the base substrate 100 is a 12-inch silicon substrate, the first length r1 may be in a range of about 147 mm to about 149 mm, and the second length r2 may be greater than the first length r1 and less than about 150 mm.

However, embodiments are not limited to a 12-inch substrate, and for example, the base substrate 100 may be an 8-inch substrate, a 16-inch substrate, or a substrate having other dimensions. When the base substrate 100 is an 8-inch substrate, the reference length r0, which is the radius of the base substrate 100, may be about 100 mm. In this case, the edge portion 104 may be an area spaced about 98 mm to about 100 mm apart from the center of the base substrate 100. For example, the edge portion 104 may be an area spaced apart from the center of the base substrate 100 by about 99.3 mm to about 100 mm.

In embodiments, when the base substrate 100 is an 8-inch silicon substrate, the first length r1 may be in a range of about 98 mm to about 99.3 mm, and the second length r2 may be greater than the first length r1 and less than about 100 mm.

When the base substrate 100 is a 16-inch substrate, the reference length r0, which is the radius of the base substrate 100, may be about 200 mm. In this case, the edge portion 104 may be an area spaced about 196 mm to about 200 mm apart from the center of the base substrate 100. For example, the edge portion 104 may be an area spaced apart from the center of the base substrate 100 by about 198.7 mm to about 200 mm.

In embodiments, when the base substrate 100 is a 12-inch silicon substrate, the first length r1 may be in a range of about 196 mm to about 198.7 mm, and the second length r2 may be greater than the first length r1 and less than about 200 mm.

That is, the radius of the edge portion 104 may also change depending on the radius of the base substrate 100. In embodiments, the radius of the edge portion 140 may be about 147/150 times to about 149/150 times the radius of the base substrate 100.

In this specification, description will focus on a case where the diameter of the base substrate 100 is 12 inches, but as described above, embodiments are not limited thereto.

Referring to FIG. 1B, an atomic concentration of nitrogen included in the inner edge portion 104a of the base substrate 100 may be a first concentration c1, and an atomic concentration of nitrogen included in the outer edge portion 104b may be a second concentration c2. In embodiments, the second concentration c2 may be greater than the first concentration c1.

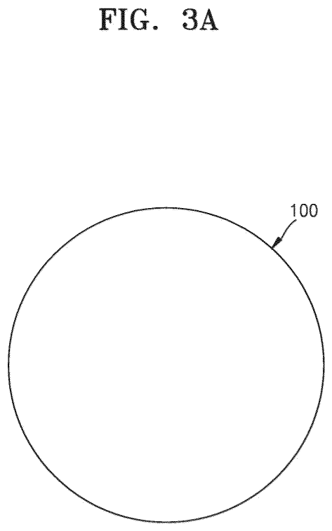

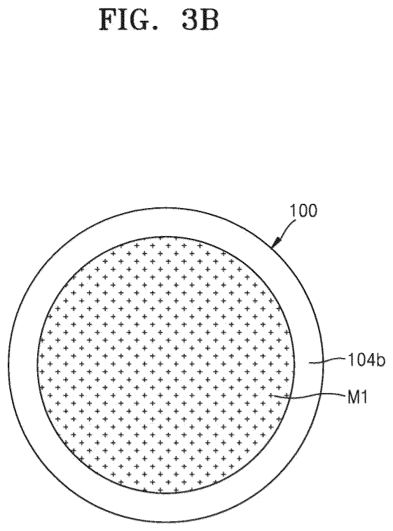

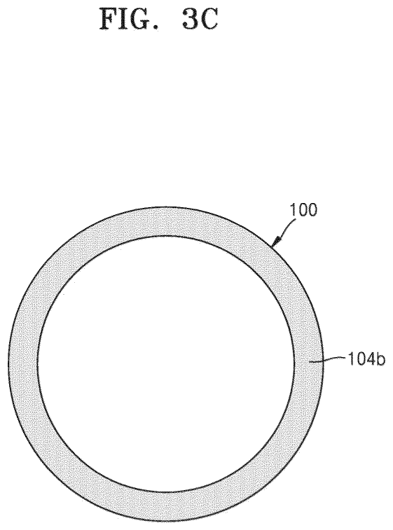

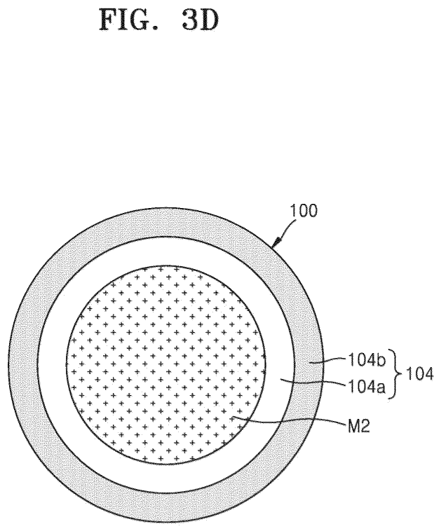

For example, the inner edge portion 104a may have a uniform nitrogen atom concentration of the first concentration c1 throughout the entire area, and the outer edge portion 104b may have a uniform nitrogen atom concentration of the second concentration c2 throughout the entire area, but a discontinuous change in nitrogen atom concentration change may occur at a boundary portion between the inner edge portion 104a and the outer edge portion 104b. The above-described features are described below with reference to a manufacturing process of the nitrogen-doped silicon substrate 10 with reference to FIGS. 3A to 3D.

In embodiments, the first concentration c1 and the second concentration c2 may each be in a range between about 1×10¹⁰ atom/cm³ and about 1×10¹⁹ atom/cm³. The central portion 102 of the substrate may not include nitrogen atoms. For example, the central portion 102 of the base substrate 100 may include only trace amounts of nitrogen. The nitrogen in the edge portion 104 may strengthen and improve mechanical stability of the base substrate, and because the central portion 102 does not include nitrogen, devices formed thereon are not affected by nitrogen.

In some embodiments, the edge portion 104 may include elements such as

carbon and oxygen together with nitrogen atoms. For example, the edge portion 104 may include SiCN. In this specification, expressions such as ‘nitrogen atom’ and ‘nitrogen’ are used for convenience of explanation, but even when the edge portion 104 includes some carbide compounds, this may affect the first concentration c1 and the second concentration c2 in the same way as when only nitride series compounds are included.

In FIG. 1A and FIG. 1B, the edge portion 104 is illustrated as including only the outer edge portion 104b and the inner edge portion 104a, but this is only an example, and the edge portion 104 may be a collection of three or more edge areas that have different nitrogen concentrations. That is, there may be three or more edge areas that surround the central portion 102 in a ring shape, and the edge areas may have a higher nitrogen concentration as the edge areas are positioned further from the center of the base substrate 100, and may have discontinuous nitrogen concentration changes at each boundary. In this case, the nitrogen concentrations included in three or more edge areas may all have different values between about 1×10¹⁰ atom/cm³ and about 1×10¹⁹ atom/cm³.

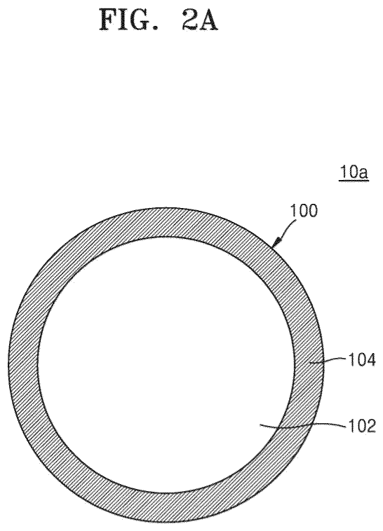

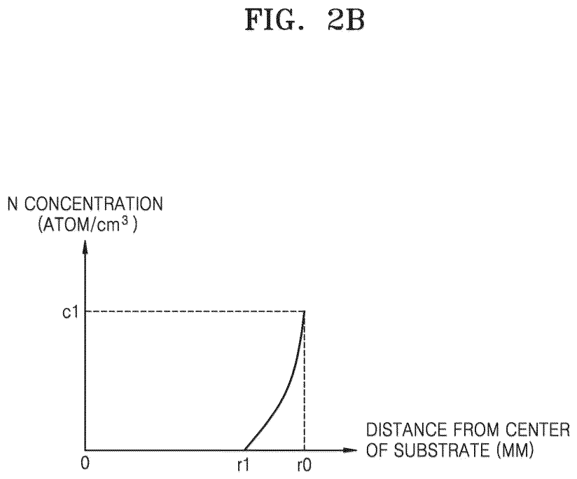

FIG. 2A illustrates a schematic drawing of a nitrogen-doped silicon substrate 10a according to an embodiment, and FIG. 2B is a graph showing a nitrogen concentration included in the nitrogen-doped silicon substrate 10a of FIG. 2A.

Referring to FIGS. 2A and 2B, the nitrogen-doped silicon substrate 10a may be the base substrate 100 including the edge portion 104 and the central portion 102.

The base substrate 100 may include a first surface and a second surface facing away from each other, and the surface illustrated in FIG. 2A may be the first surface of the base substrate 100. Because the base substrate 100 and the central portion 102 of FIG. 2A may be substantially identical to the base substrate 100 and the central portion 102 of FIG. 1A, respectively, a detailed description of the base substrate 100 and the central portion 102 may be omitted.

Referring again to FIG. 2A together with FIG. 2B, when the radius of the base substrate 100 is defined as the reference length r0, an area from the center of the base substrate 100 to the first length r1 may correspond to the central portion 102 of the base substrate 100, and an area spaced apart from the center of the base substrate 100 by a length greater than the first length r1 and less than or equal to the reference length r0 may correspond to the edge portion 104 of the base substrate 100.

In embodiments, a concentration gradient of nitrogen included in the edge portion 104 that surrounds the central portion 102 of the base substrate 100 in a ring shape may change continuously depending on a distance from the center of the base substrate 100, unlike the concentration gradient of nitrogen included in the edge portion 104 shown in FIGS. 1A and 1B.

In more detail, the concentration of nitrogen included in the edge portion 104 may increase as distance from the center of the base substrate 100 increases.

In FIG. 2B, it is shown that the nitrogen concentration included in the edge portion 104 increases steeply as distance from the center of the base substrate 100 increases, but embodiments are not necessarily limited thereto. For example, the concentration of nitrogen included in the edge portion 104 may increase with a relatively constant slope regardless of the distance from the center of the base substrate 100, and the change in slope may decrease as the distance increases.

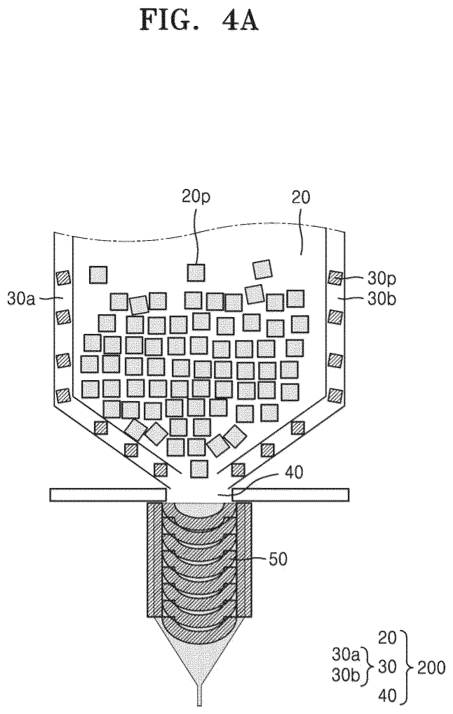

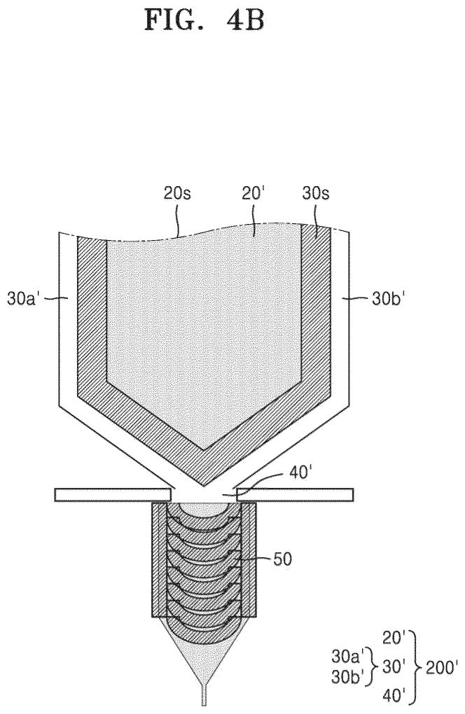

The nitrogen-doped silicon substrate 10a of FIG. 2A may have a continuous change in nitrogen atom concentration, unlike the nitrogen-doped silicon substrate 10 of FIG. 1A. The features are described below with reference to the manufacturing process of the nitrogen-doped silicon substrate 10a with reference to FIGS. 4A and 4B.

The concentration of nitrogen included in the edge portion 104 may have various values from 0 to a reference concentration c0. In embodiments, the reference concentration c0 may range from about 1×10¹⁰ atom/cmto about 1×10¹⁹ atom/cm³. The central portion 102 of the substrate may not include nitrogen atoms. For example, the central portion 102 of the base substrate 100 may include only trace amounts of nitrogen. The nitrogen in the edge portion 104 may strengthen and improve mechanical stability of the base substrate, and because the central portion 102 does not include nitrogen, devices formed thereon are not affected by nitrogen.

In some embodiments, the edge portion 104 may include elements such as carbon and oxygen together with nitrogen atoms. For example, the edge portion 104 may also include SiCN. In this specification, expressions such as ‘nitrogen atom’ and ‘nitrogen’ are used for convenience of explanation, but even when the edge portion 104 includes some carbide compounds, this may affect the reference concentration c0 in the same way as when only nitride series compounds are included.

In embodiments, the base substrate 100 may be a 12-inch silicon substrate. When the base substrate 100 is a 12-inch silicon substrate, the reference length r0, which is the radius of the base substrate 100, may be about 150 mm, and the first length r1 may be in a range of about 147 mm to about 149 mm. In this case, the edge portion 104 corresponds to an area spaced apart from the center of the base substrate 100 by a distance greater than the first length r1 and less than or equal to the reference length r0, so when the first length r1 is about 147 mm, the edge portion 104 may be an area spaced apart from the center of the base substrate 100 by about 147 mm to about 150 mm, and when the first length r1 is about 149 mm, the edge portion 104 may be an area spaced apart from the center of the base substrate 100 by about 149 mm to about 150 mm.

However, embodiments are not limited to a 12-inch substrate, and for example, the base substrate 100 may be an 8-inch substrate, a 16-inch substrate, or any substrate having other dimensions.

In embodiments, when the base substrate 100 is an 8-inch substrate, the reference length r0, which is the radius of the base substrate 100, may be about 100 mm, and the first length r1 may be in a range of about 98 mm to about 99.3 mm. In this case, the edge portion 104 corresponds to an area spaced apart from the center of the base substrate 100 by a distance greater than the first length r1 and less than or equal to the reference length r0, so when the first length r1 is about 98 mm, the edge portion 104 may be an area spaced apart from the center of the base substrate 100 by about 98 mm to about 100 mm, and when the first length r1 is about 99.3 mm, the edge portion 104 may be an area spaced apart from the center of the base substrate 100 by about 99.3 mm to about 100 mm.

In embodiments, when the base substrate 100 is a 16-inch substrate, the reference length r0, which is the radius of the base substrate 100, may be about 200 mm, and the first length r1 may be in a range of about 196 mm to about 198.7 mm. In this case, the edge portion 104 corresponds to an area spaced apart from the center of the base substrate 100 by a distance greater than the first length r1 and less than or equal to the reference length r0, so when the first length r1 is about 196 mm, the edge portion 104 may be an area spaced apart from the center of the base substrate 100 by about 196 mm to about 200 mm, and when the first length r1 is about 198.7 mm, the edge portion 104 may be an area spaced apart from the center of the base substrate 100 by about 198.7 mm to about 200 mm.

That is, the radius of the edge portion 104 may also change depending on the radius of the base substrate 100. In embodiments, the radius of the edge portion 140 may be about 147/150 times to about 149/150 times the radius of the base substrate 100.

In this specification, examples are described where the diameter of the base substrate 100 is 12 inches, but as described above, embodiments are not limited thereto.

FIGS. 3A to 3D are drawings sequentially illustrating a method of manufacturing the nitrogen-doped silicon substrate 10, according to an embodiment. The method of manufacturing the nitrogen-doped silicon substrate 10 described with reference to FIGS. 3A to 3D may be a method of selectively doping nitrogen in an edge area of an individual silicon wafer obtained by cutting a silicon ingot.

Referring to FIG. 3A, the base substrate 100 may be prepared. The base substrate 100 may be a result obtained by cutting the silicon ingot, and the base substrate 100 may be a silicon substrate that does not contain nitrogen. For example, the silicon substrate may include only trace amounts of nitrogen.

Referring to FIG. 3B, a first mask M1 may be arranged on the base substrate 100. The first mask M1 may be arranged to vertically overlap the base substrate 100 and may have a smaller plane area than the base substrate 100. For example, a portion of the base substrate 100 may extend past the first mask M1. Although the base substrate 100 and the first mask M1 are both illustrated as having a circular shape, embodiments are not limited thereto.

The area not covered by the first mask M1 may be defined as the outer edge portion 104b.

Referring to FIG. 3B, nitrogen doping (hereinafter referred to as “primary doping”) is performed at a certain concentration on the outer edge portion 104b.

Referring to FIG. 3C, the first mask M1 may then be removed. Nitrogen may not penetrate into the area covered by the first mask M1, and nitrogen atoms may be doped only to the outer edge portion 104b.

In embodiments, rapid thermal annealing (RTA) and/or plasma may be used for nitrogen doping.

Referring to FIG. 3D, a second mask M2 may be arranged in an area surrounded by an outer edge portion 104b on the base substrate 100. The second mask M2 may be arranged to vertically overlap the base substrate 100 and may have a less planar area than the first mask M1 (see FIG. 3B). The second mask M2 is depicted as having a circular shape, but embodiments are not limited thereto.

The area not covered by the second mask M2, excluding the outer edge portion 104b may be defined as the inner edge portion 104a.

Next, nitrogen doping (hereinafter referred to as “secondary doping”) is performed at a certain concentration on the inner edge portion 104a and the outer edge portion 104b. When the second mask M2 is removed, a result of FIG. 1A may be obtained.

The nitrogen may not penetrate into the area covered by the second mask M2, and nitrogen atoms may be doped only on the outer edge portion 104b and the inner edge portion 104a. In embodiments, RTA and/or plasma may be used for nitrogen doping.

When comparing the primary doping with the secondary doping, the concentrations of nitrogen atoms doped in the two doping processes of the primary doping and the secondary doping may be the same or different. For example, the concentration of nitrogen atoms doped in the primary doping may be greater or less than the concentration of nitrogen atoms doped in the secondary doping.

In embodiments, while the inner edge portion 104a was doped with nitrogen atoms by the secondary doping process, the outer edge portion 104b was doped with nitrogen atoms by both the first and secondary doping processes. Therefore, in the result of FIG. 1A, the concentration of nitrogen atoms included in the outer edge portion 104b may be greater than the concentration of nitrogen atoms included in the inner edge portion 104a (see FIG. 1B).

In addition, because a mask is formed in an area where nitrogen doping is not performed during both the primary doping and the secondary doping, the concentration of nitrogen atoms may change discontinuously at the boundary between the central portion 102 and the inner edge portion 104a and the boundary between the inner edge portion 104a and the outer edge portion 104b.

In addition, carbide series materials as well as nitride series materials may be doped together in the primary doping and/or the secondary doping. For example, a dopant may include SiCN, and the dopant may also include oxygen atoms.

Because a size of the outer edge portion 104b may be determined by a size of the first mask M1, and a size of the inner edge portion 104a may be determined by a size of the second mask M2, the sizes of the outer edge portion 104b and the inner edge portion 104a may be set by adjusting the sizes of the first mask M1 and the second mask M2.

Although FIG. 1A illustrates that the edge portion 104 includes two edge areas and has one concentration-changing boundary surface, in some other embodiments, the edge portion 104 may include N (N is a natural number greater than or equal to 3) edge areas and have N-1 concentration-changing boundary surfaces.

When the edge portion 104 includes N edge areas, N masks having different sizes may be used, and the same process as described above with reference to FIGS. 3A and 3D may be repeated to form N edge areas. When multiple masks are used, the area of the masks used in each process is less than the area of the masks used in the previous process. Therefore, the edge area that is further from the center of the base substrate 100 is more exposed to the nitrogen doping process, and the edge area may therefore have a higher nitrogen concentration. In this case, the nitrogen concentrations included in the N edge areas may all have different values between about 1×10¹⁰ atom/cm³ and about 1×10¹⁹ atom/cm³. In addition, although the nitrogen doping process is shown to be performed

only on the first surface of the base substrate 100 in FIGS. 3A to 3D, embodiments are not limited thereto. In some embodiments, the process described with reference to FIGS. 3A to 3D may be performed only on the second surface of the base substrate 100. Alternatively, in some other embodiments, after performing the process described with reference to FIGS. 3A to 3D on the first surface of the base substrate 100, the process described with reference to FIGS. 3A to 3D may be performed again on the second surface, thereby forming a nitrogen concentration gradient at the edge portion 104 on both surfaces of the base substrate 100.

When the processes of FIGS. 3A to 3D are performed on the second surface of the base substrate 100, there may be relatively fewer restrictions on the size of the mask compared to when the processes of FIGS. 3A to 3D are performed on the first surface. That is, when performing a process on the second surface, a smaller mask may be used compared to when performing a process on the first surface. This may be because the second surface of the base substrate 100 has less electrical influence on the element area compared to the first surface.

The method of manufacturing the nitrogen-doped silicon substrate 10 described with reference to FIGS. 3A to 3D has the advantage of being able to easily control the possibility of warpage of the substrate by controlling the size of the area where nitrogen is doped (i.e., the size of the mask), the number of masks, the nitrogen doping concentration, etc., by user settings.

FIGS. 4A and 4B are cross-sectional views schematically illustrating a manufacturing process of the nitrogen-doped silicon substrate 10a (see FIG. 2A), according to an embodiment, respectively.

In the manufacturing process of the nitrogen-doped silicon substrate 10a described with reference to FIGS. 4A and 4B, a float zone method may be applied. In general, the float zone method may be a method of inducing crystal growth by locally heating a silicon rod which has a rod shape.

The float zone method may be started by preparing a high-purity single-crystal silicon seed and a polycrystalline silicon rod, and melting a portion of the polycrystalline silicon rod by using an induction heating device. In this case, the induction heating device may melt only a portion of the polycrystalline silicon rod, and a molten area of the polycrystalline silicon rod may move along the entire rod.

As the molten area moves, the remaining silicon in the single crystal silicon rod, excluding the molten area, cools and solidifies into a single crystal structure. The seed single crystal structure is transferred to the polycrystalline silicon rod through the molten area, so that the entire silicon rod may grow into a single crystal structure. The molten silicon area pushes out impurities as the molten silicon area moves, and by repeating the above process, a high-purity silicon ingot may be formed.

According to the float zone method, an ingot having a lower impurity concentration may be obtained compared to an ingot formed by the Czochralski method because the molten area pushes out the impurities, and because melting occurs only locally, a container to contain the silicon is not required, so the possibility of inclusion of impurities from the container may be prevented.

Referring again to FIG. 4A, an ingot manufacturing device 200 including a mold 20, a first nitrogen powder injection path 30a, a second nitrogen powder injection path 30b, and a nozzle 40 may be prepared.

The ingot manufacturing device 200 in FIG. 4A may manufacture an ingot by using a silicon powder 20p.

In embodiments, the silicon powder 20p may be high-purity Si powder that does not include impurities. In addition, a nitrogen powder 30p injected through the first nitrogen powder injection path 30a and the second nitrogen powder injection path 30b may include a nitride series material.

First, the silicon powder 20p may be put in the mold 20 which is cylindrical and compressed at a certain pressure to form a preform. In embodiments, the preform may be a tightly compressed lump of silicon powder in a polycrystalline state.

Using an induction heating device from one end of the preform, a localized molten zone is formed, and the molten zone moves slowly, allowing the solidified portion to recrystallize into a single crystal structure. In some embodiments, single crystal seeds may be used to guide growth direction.

When the preform in the mold 20 is single-crystallized and comes out as an ingot 50 through the nozzle 40, the edge of the ingot 50 may be doped with nitrogen by the nitrogen powder 30p injected into the first nitrogen powder injection path 30a and the second nitrogen powder injection path 30b. In some embodiments, a heat treatment process may be performed simultaneously with the nitrogen doping process at the edge.

FIG. 4A illustrates a cross-sectional view of the ingot manufacturing device 200, in which the first nitrogen powder injection path 30a and the second nitrogen powder injection path 30b are illustrated as if they surround both side surfaces of the mold 20, respectively. However, embodiments are not limited thereto and the first nitrogen powder injection path 30a and the second nitrogen powder injection path 30b may have a structure in which they are formed integrally, wrapping around the mold 20 in a ring shape from a planar perspective. That is, the first nitrogen powder injection path 30a and the second nitrogen powder injection path 30b may be connected to each other in a ring shape to form one nitrogen powder injection path 30 connected in a ring shape.

As a result, the ingot 50 formed by the ingot manufacturing device 200 of FIG. 4A may be sliced to obtain the nitrogen-doped silicon substrate 10a as shown in FIG. 2A.

According to the manufacturing method of the ingot 50 illustrated in FIG. 4A, the ingot 50 is already doped with nitrogen at the edge by the nitrogen powder 30p supplied by the nitrogen powder injection path 30, before being sliced into a substrate. Therefore, unlike the process of selectively doping nitrogen on one surface of the base substrate 100 described with reference to FIGS. 3A to 3D, the nitrogen-doped silicon substrate 10a may be equally doped with nitrogen at the edge without distinction between the first surface and the second surface.

FIG. 4B is a cross-sectional view schematically illustrating a manufacturing process of a nitrogen-doped silicon substrate 10a according to an embodiment.

Referring to FIG. 4B, an ingot manufacturing device 200′ including a mold 20′, a first nitrogen coating portion 30a′, a second nitrogen coating portion 30b′, and a nozzle 40′ may be prepared.

The manufacturing process of the nitrogen-doped silicon substrate 10a described with reference to FIG. 4A is a method of injecting silicon powder 20p and nitrogen powder 30p into a mold 20 and a nitrogen powder injection path 30, respectively, and then manufacturing the ingot 50 by separating the silicon powder injection path and the nitrogen powder injection path from each other. In comparison, the manufacturing process of the nitrogen-doped silicon substrate 10a described with reference to FIG. 4B may be a method of coating the edge of a polycrystalline silicon rod 20s with a nitride material in the float zone method and then growing the edge of the polycrystalline silicon rod 20s into an ingot.

The first nitrogen coating portion 30a′ and the second nitrogen coating portion 30b′ of FIG. 4B are depicted as wrapping around both side surfaces of the mold 20′, similar to the first nitrogen powder injection path 30a and the second nitrogen powder injection path 30b of FIG. 4A, respectively. However, the first nitrogen coating portion 30a′ and the second nitrogen coating portion 30b′ may have a structure in which they are formed integrally, wrapping around the mold 20′ in a ring shape from a planar perspective. That is, the first nitrogen coating portion 30a′ and the second nitrogen coating portion 30b′ may be connected to each other in the ring shape to form one nitrogen coating portion 30.

The nitrogen coating portion 30 may heat the side surface 30s of the polycrystalline silicon rod, which is a part of the polycrystalline silicon rod 20s placed in the mold 20, and may dope the side surface 30s of the polycrystalline silicon rod with a nitride series material. The doped nitride series material is doped around the edge of the polycrystalline silicon rod 20s and does not penetrate into the interior of the polycrystalline silicon rod 20s beyond a predetermined depth. Therefore, when the ingot 50 obtained by the process is sliced, the nitrogen-doped silicon substrate 10a as shown in FIG. 2A may be obtained.

The side surface 30s of the polycrystalline silicon rod illustrated in FIG. 4B may represent an area where nitrogen is doped by the nitrogen coating portion 30′ in the cylindrical polycrystalline silicon rod 20s.

According to the manufacturing method of the ingot 50 illustrated in FIG. 4B, the ingot 50 is already doped with nitrogen on its side surface 30s by the nitride material and heat supplied by the nitrogen coating portion 30′ before being sliced into a substrate. Therefore, unlike the process of selectively doping nitrogen on one surface of the base substrate 100 described with reference to FIGS. 3A to 3D, the nitrogen-doped silicon substrate 10a may be equally doped with nitrogen on the edge portion without distinction between the first surface and the second surface.

Although specific terms have been used to describe embodiments in this specification, they have been used only for the purpose of explaining the technical idea of the inventive concept and are not intended to limit the meaning or the scope of the inventive concept set forth in the claims. Therefore, a person having ordinary skill in the art will understand that various modifications and equivalent other embodiments are possible therefrom. Therefore, the true technical protection scope of the inventive concept should be determined by the technical idea of the appended claims.

While aspects of embodiments have been particularly shown and described, it will be understood that various changes in form and details may be made therein without departing from the spirit and scope of the following claims.

What is claimed is:

1. A method of manufacturing a nitrogen-doped silicon substrate, the method comprising:
preparing a base substrate which is circular and comprises a central portion, an inner edge portion surrounding the central portion in a ring shape, and an outer edge portion surrounding the inner edge portion in a ring shape, the base substrate comprising a first surface and a second surface opposite to the first surface;
providing a first mask on the first surface of the base substrate to cover the central portion and the inner edge portion, and to expose the outer edge portion;
performing a primary doping operation of doping nitrogen on the outer edge portion while the first mask is on the first surface of the base substrate;
removing the first mask and providing a second mask on the first surface of the base substrate to cover the central portion, and to expose the outer edge portion and the inner edge portion;
performing a secondary doping operation of doping nitrogen on the outer edge portion and the inner edge portion while the second mask is on the first surface of the base substrate; and
removing the second mask,
wherein an atomic concentration of nitrogen in the inner edge portion is constant at a first concentration, an atomic concentration of nitrogen in the outer edge portion is constant at a second concentration, and
wherein an atomic concentration of nitrogen changes discontinuously from the first concentration to the second concentration at a boundary between the outer edge portion and the inner edge portion.

2. The method of claim 1, wherein the second concentration is greater than the first concentration.

3. The method of claim 1, wherein the first concentration and the second concentration are in a range between 1×10¹⁰ atom/cm³ and 1×10¹⁹ atom/cm³.

4. The method of claim 1, wherein the outer edge portion and the inner edge portion each further comprise a carbide compound.

5. The method of claim 1, wherein concentrations of nitrogen doped in the primary doping and the secondary doping are different from each other.

6. The method of claim 1, wherein a common concentration of nitrogen is doped in both the primary doping operation and the secondary doping operation.

7. The method of claim 1, wherein the primary doping operation and the secondary doping operation are performed using rapid thermal annealing (RTA) or plasma.

8. The method of claim 1, wherein a radius of the second mask is in a range of 147/150 times to 149/150 times a length of a radius of the base substrate.

9. The method of claim 1, wherein the outer edge portion and the inner edge portion have a higher strength than the central portion.

10. The method of claim 1, further comprising:
providing a third mask having a smaller cross-sectional area than the base substrate on the second surface of the base substrate;
doping nitrogen in an area exposed by the third mask on the second surface of the base substrate;
removing the third mask and providing a fourth mask having a smaller cross-sectional area than the third mask on the second surface of the base substrate;
doping nitrogen in an area exposed by the fourth mask on the second surface of the base substrate; and
removing the fourth mask.

11. The method of claim 10, wherein a nitrogen concentration gradient of the second surface of the base substrate is different than a nitrogen concentration gradient of the first surface of the base substrate.

12. A method of manufacturing a nitrogen-doped silicon substrate, the method comprising:
injecting a silicon powder into a cylindrical mold of an ingot manufacturing device;
injecting a nitride powder into a nitrogen powder injection path in the ingot manufacturing device, wherein the nitrogen powder injection path surrounds the cylindrical mold in a ring shape;
applying a first pressure to compress the silicon powder and form a silicon powder lump in a polycrystalline state;
applying heat to the silicon powder lump and recrystallizing the silicon powder lump into a single crystal structure;
forming an ingot from the silicon powder lump; and
slicing the ingot to form individual substrates,
wherein, in the recrystallizing of the silicon powder lump, nitrogen is doped on a side surface of the ingot by the nitride powder injected through the nitrogen powder injection path.

13. The method of claim 12, wherein at least one of the individual substrates comprises a nitrogen doping area formed in a ring shape at an edge portion, and
wherein a concentration of nitrogen in the nitrogen doping area increases as a distance from a center of a corresponding individual substrate increases.

14. The method of claim 13, wherein the concentration of nitrogen in the nitrogen doping area changes continuously depending on the distance from the center of the corresponding individual substrate.

15. The method of claim 13, wherein the nitrogen doping area further comprises a carbide compound.

16. The method of claim 13, wherein at least one of the individual substrates comprises a first surface and a second surface opposite to the first surface, and
wherein the first surface and the second surface share a common nitrogen concentration gradient of the nitrogen doping area.

17. A method of manufacturing a nitrogen-doped silicon substrate, the method comprising:
in an ingot manufacturing device comprising a cylindrical mold and a nitrogen coating portion wrapping around the cylindrical mold in a ring shape, forming a polycrystalline silicon rod within the cylindrical mold;
heating, by the nitrogen coating portion, a side surface of the polycrystalline silicon rod placed within the cylindrical mold;
doping a nitride series material on the side surface of the polycrystalline silicon rod;
recrystallizing the polycrystalline silicon rod into an ingot; and
slicing the ingot to form individual substrates,
wherein at least one of the individual substrates comprises a nitrogen doping area formed in a ring shape at an edge portion.

18. The method of claim 17, wherein the nitrogen doping area has a higher concentration of nitrogen as a distance of the nitrogen doping area from a center of each of individual substrates increases, and a change in concentration of nitrogen is continuous.

19. The method of claim 17, wherein at least one of the individual substrates comprises a first surface and a second surface opposite to the first surface, and
wherein the first surface and the second surface share a common nitrogen concentration gradient of the nitrogen doping area.

20. The method of claim 17, wherein the nitrogen doping area further comprises a carbide compound.
